(19) United States
(12) Patent Application Publication
(10) Pub. No.: US 2011/0073832 A1
(43) Pub. Date: Mar. 31, 2011

(54) PHASE-CHANGE MEMORY DEVICE

(76) Inventors: Hyun-Seok LIM, Suwon-si (KR); Shin-Jae Kang, Yongin-si (KR); Tai-Soo Lim, Seoul (KR); Jong-Cheol Lee, Seoul (KR); Jae-Hyoung Choi, Hwaseong-si (KR)

(21) Appl. No.: 12/892,419

(22) Filed: Sep. 28, 2010

(30) Foreign Application Priority Data
Sep. 29, 2009 (KR) 10-2009-0092625

(51) Int. Cl. H01L 45/00

(52) U.S. Cl. 257/4; 257/E45.001

(57) ABSTRACT

A phase-change memory device, including a lower electrode, a phase-change material pattern electrically connected to the lower electrode, and an upper electrode electrically connected to the phase-change material pattern. The lower electrode may include a first structure including a metal semiconductor compound, a second structure on the first structure, the second structure including a metal nitride material, and including a lower part having a greater width than an upper part, and a third structure including a metal nitride material containing an element X, the third structure being on the second structure, the element X including at least one selected from the group of silicon, boron, aluminum, oxygen, and carbon.

### BACKGROUND

1. Field

Example embodiments relate to a phase-change memory device including a phase-change material, the phase of which is changed by heat.

2. Description of Related Art

A phase-change memory device may be used to store information based on a state of a phase-change material in the device. A reduction in power consumption is desirable for providing a high degree of integration for a phase-change memory.

### SUMMARY

It is a feature of an embodiment to provide a phase-change memory device having a lower electrode including a lower part having a low resistance and an upper part having a high resistance.

At least one of the above and other features and advantages may be realized by providing a phase-change memory device, including a lower electrode, a phase-change material pattern electrically connected to the lower electrode, and an upper electrode electrically connected to the phase-change material pattern. The lower electrode may include a first structure including a metal semiconductor compound, a second structure on the first structure, the second structure including a metal nitride material, and including a lower part having a greater width than an upper part, and a third structure including a metal nitride material containing an element X, the third structure being on the second structure, the element X including at least one selected from the group of silicon, boron, aluminum, oxygen, and carbon.

The second structure may include a lower part having a first width and an upper part having a second width smaller than the first width, and the upper part of the second structure may vertically extend from a top surface of the lower part.

The second structure may be in the shape of an “L” and the second structure may include a first vertical surface, a first horizontal surface horizontally extending from a lower part of the first vertical surface, a second horizontal surface horizontally extending from an upper part of the first vertical surface, a third horizontal surface parallel to the second horizontal surface and spaced apart a predetermined space therefrom, a second vertical surface connecting the second horizontal surface to the third horizontal surface, and a third vertical surface connecting the first horizontal surface to the third horizontal surface.

The third structure may be on the second horizontal surface.

The device may further include an insulating pattern adjacent to the first vertical surface and the third vertical surface. An upper part of the insulating pattern may include an oxide material containing the element X or a nitride material containing the element X.

The upper part of the insulating pattern may have a same thickness and level as the third structure.

The third structure may be on the second vertical surface and the third horizontal surface.

The first structure may include titanium silicide, the second structure may include titanium nitride material, and the third structure may include titanium nitride material containing the element X.

The device may further include a fourth structure including a metal oxide material between the second structure and the third structure.

The fourth structure may include titanium oxide material.

The device may further include a fourth structure including titanium nitride material containing an element Y on the third structure. The element Y may include at least one selected from the group of silicon, boron, aluminum, oxygen, and carbon.

The element Y may be different from the element X.

The device may further include a lower structure formed below the first structure and including silicon. The first and second structures may be formed by forming a metal layer on the lower structure and nitriding the result.

The metal layer may include titanium.

The third structure may be formed by performing a thermal or plasma treatment using a first precursor containing nitrogen and a second precursor containing the element X on the second structure.

The element X may be Si, and the second precursor may include at least one selected from the group of SiH₄, Si₂H₆, Si₃H₈, SiCl₂H₂, and bis(tertiary-butylamino)silane.

The element X may be boron, and the second precursor may include at least one selected from the group of B₂H₆ and triethylborate.

The element X may be aluminum, and the second precursor may include at least one selected from the group of AlCl₃, tetra ethyl methyl amide hafnium, dimethyl aluminum hydride, and dimethylethylamine alane.

The element X may be oxygen, and the second precursor may include at least one selected from the group of oxygen gas and ozone gas.

The element X may be carbon, and the second precursor may include C₂H₄.

### BRIEF DESCRIPTION OF THE DRAWINGS

The above and other features and advantages will become more apparent to those of skill in the art by describing in detail example embodiments with reference to the attached drawings, in which:

FIG. 1 illustrates an equivalent circuit diagram of a memory device according to an example embodiment.

FIG. 2 illustrates a plan view of the memory device illustrated in FIG. 1.

FIG. 3 illustrates a cross-sectional view of a memory device according to an example embodiment.

FIG. 4 illustrates a schematic cross-sectional view of a phase-change memory device according to another example embodiment.

FIG. 5 illustrates a schematic cross-sectional view of a phase-change memory device according to still another example embodiment.

FIG. 6 illustrates a schematic cross-sectional view of a phase-change memory device according to yet another example embodiment.

FIGS. 7 to 16 illustrate schematic cross-sectional views of stages in a method of forming the phase-change memory device illustrated in FIG. 3.

FIG. 18 illustrates a schematic cross-sectional view of a phase-change memory device according to yet another example embodiment.

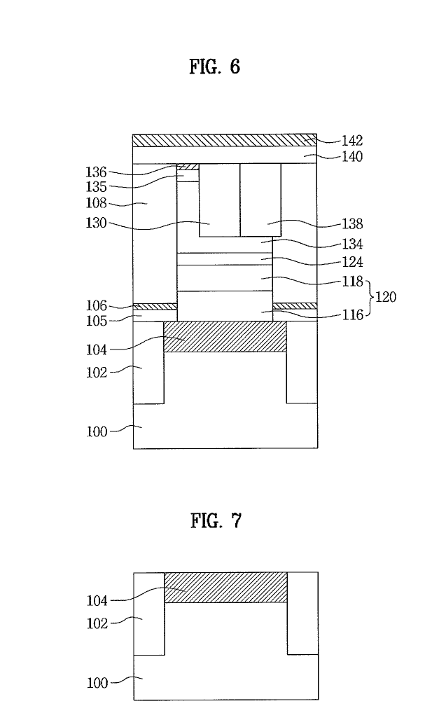

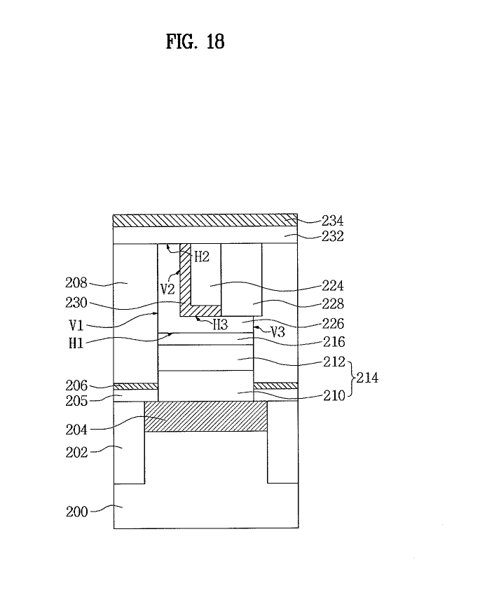

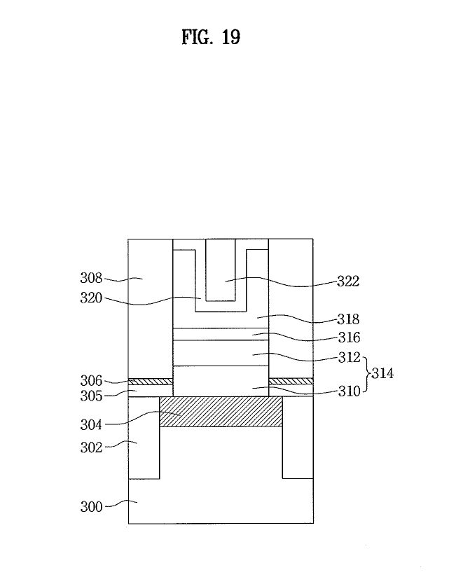

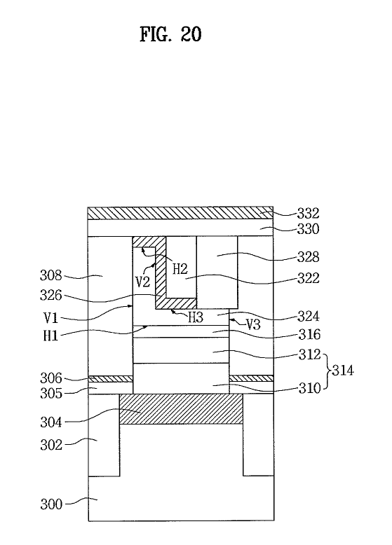

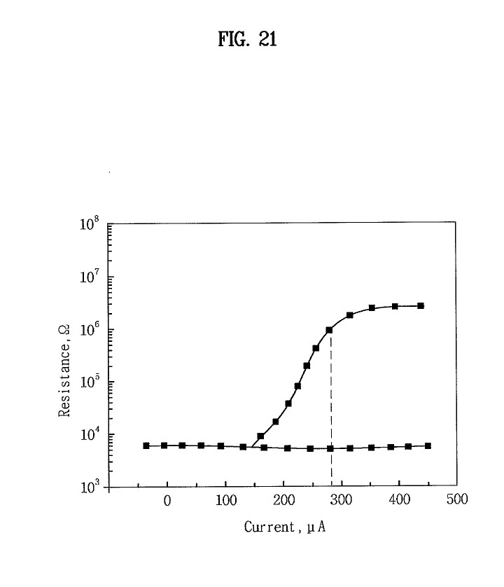

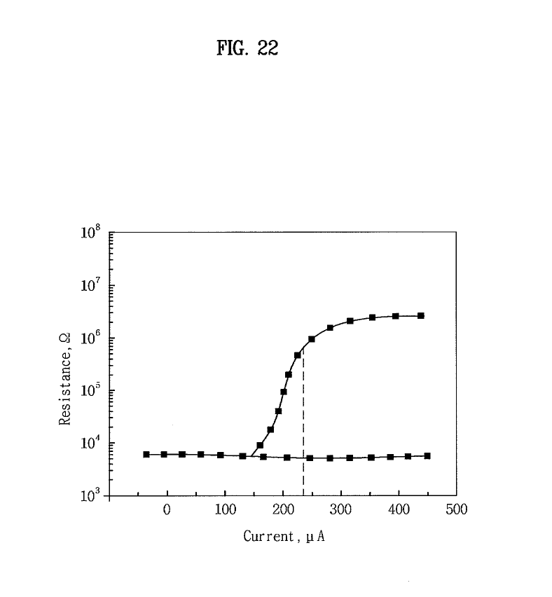

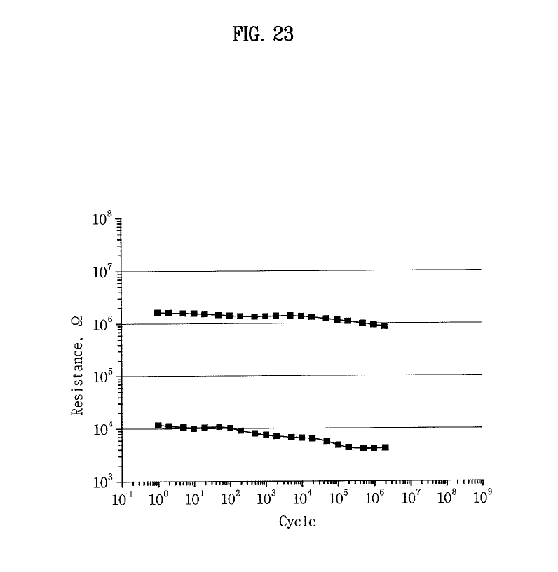

FIGS. 6 to 12 and 17 illustrate schematic cross-sectional views of stages in a method of forming the phase-change memory device illustrated in FIG. 18.

FIG. 20 illustrates a schematic cross-sectional view of a phase-change memory device according to yet another example embodiment.

FIGS. 6 to 12 and 19 illustrate schematic cross-sectional views of stages in a method of forming the phase-change memory device illustrated in FIG. 20.

FIG. 21 illustrates transition characteristics of a conventional phase-change memory device.

FIG. 22 illustrates transition characteristics of a phase-change memory device according to a first example embodiment.

FIG. 23 illustrates endurance characteristics of the phase-change memory device according to the first example embodiment.

### DETAILED DESCRIPTION

Korean Patent Application No. 10-2009-0092615, filed on Sep. 29, 2009, in the Korean Intellectual Property Office, and entitled: “Phase-Change Memory Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

### First Example Embodiment

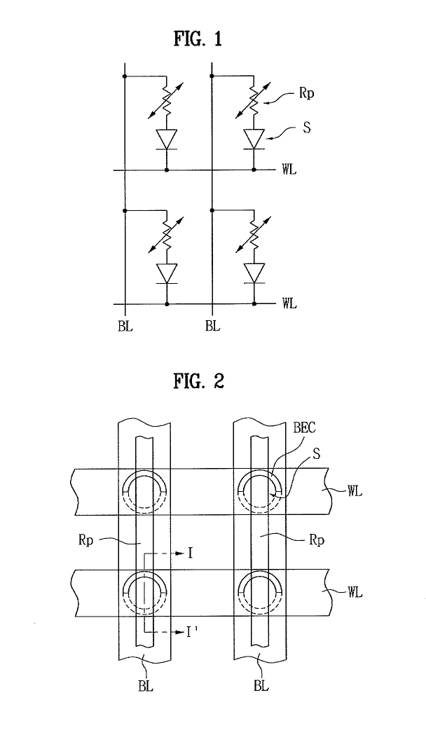

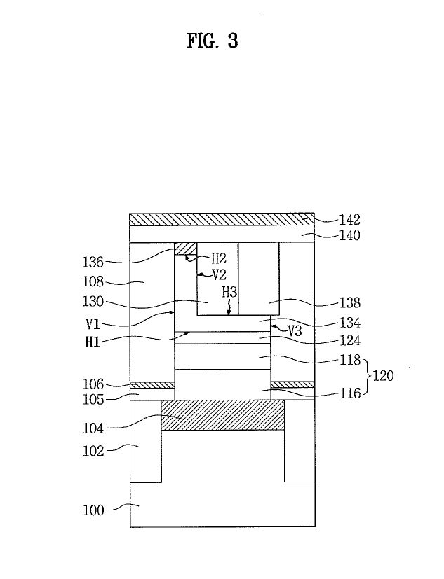

FIG. 1 illustrates an equivalent circuit diagram of a memory device according to an example embodiment, FIG. 2 illustrates a plan view of the memory device illustrated in FIG. 1, and FIG. 3 illustrates a cross-sectional view of a memory device according to an example embodiment.

According to example embodiments, the memory device illustrated in FIGS. 1 to 3 is a phase-change memory device.

Referring to FIGS. 1 and 2, the memory device may include bit lines BL, word lines WL, phase-change material patterns Rp, and switching devices S.

Each of the bit lines BL may extend in a first direction, and may be arranged at the same interval in a direction perpendicular to the extending direction.

Each of the word lines WL may extend in a second direction different from the first direction, and may be arranged at the same interval in a direction perpendicular to the extending direction. For example, the first direction may be perpendicular to the second direction.

The bit lines BL may be formed to cross the word lines WL. The switching devices S may be formed at intersections of the bit lines BL and the word lines WL.

The switching devices S may be electrically connected to the word lines WL.

The phase-change material patterns Rp may be formed between the bit lines

BL and the switching devices S. The phase-change material patterns Rp may function as data storage elements. Also, the switching devices S may be electrically connected to each other via a lower electrode BEC to correspond to the phase-change material patterns Rp. As a result, the bit lines BL may be electrically connected to the word lines WL via the phase-change material patterns Rp, the lower electrode BEC and the switching devices S.

The memory device will be described in further detail below.

Referring to FIG. 3, a memory device may include a word line 104 formed on a substrate 100, a switching device 120, insulating patterns 108, 130, and 138, lower electrodes 124, 134, and 136, a phase-change material pattern 140, and an upper electrode 142.

The substrate 100 may include a field region and an active region. The field region may be formed by an isolation pattern 102. The active region may be defined by the field region. For example, the active region may be in the shape of a line extending in a first direction.

The word line 104 may be formed in the substrate 100. According to example embodiments, the word line 104 may be in the shape of a line extending in the second direction. In an implementation, the word line 104 may be formed in the substrate 100 and a top surface of the word line 104 may have substantially the same level as that of the substrate 100. The word line 104 may be formed of a conductive material such as impurity-doped silicon, a metal, or a metal compound.

A buffer layer 105 and/or an etch stop layer 106 may be disposed on the isolation pattern 102.

The switching device 120 may be formed to be electrically connected to the word line 104 on the substrate 100.

According to an example embodiment, the switching device 120 may be a diode 120. The diode 120 may include a lower silicon pattern 116 doped with a first impurity, and an upper silicon pattern 118 doped with a second impurity. The first and second impurities may include at least one selected from the Group III elements or the Group V elements of the periodic table. The first and second impurities may be substantially different from each other. For example, when the first impurity includes at least one selected from the Group III elements of the periodic table, the second impurity may include at least one selected from the Group V elements of the periodic table. Also, the diode 120 may be formed in contact with a top surface of the word line 104. For one example, the diode 120 may have a width substantially narrower than that of the word line 104. For another example, the switching device 120 may have substantially the same width as that of the word line 104.

According to other example embodiments, the switching device 120 may be a transistor (not shown). The transistor may include a gate insulating layer, a gate electrode, and source/drain regions.

The description below sets forth examples using a diode as the switching device 120. However, embodiments are not limited to using the diode as the switching device 120.

The insulating patterns 108, 130, and 138 may include a first insulating pattern 108, a second insulating pattern 130, and a third insulating pattern 138. The insulating patterns 108, 130, and 138 may include an oxide material, a nitride material, or an oxynitride material. Examples of the oxide material, nitride material, and oxynitride material include silicon oxide material, silicon nitride material, and silicon oxynitride material, respectively. According to example embodiments, the first insulating pattern 108, the second insulating pattern 130, and the third insulating pattern 138 may include substantially the same material. According to other example embodiments, the first insulating pattern 108, the second insulating pattern 130, and the third insulating pattern 138 may include substantially different materials.

The first insulating pattern 108 may be formed to insulate between adjacent switching devices 120. According to example embodiments, the first insulating pattern 108 may be formed to be spaced by the width of the switching device 120. Further, the first insulating pattern 108 may be formed to cover a part of the word line 104 and the isolation pattern 102. A top surface of the first insulating pattern 108 may be the same level as those of the lower electrodes 124, 134, and 136.

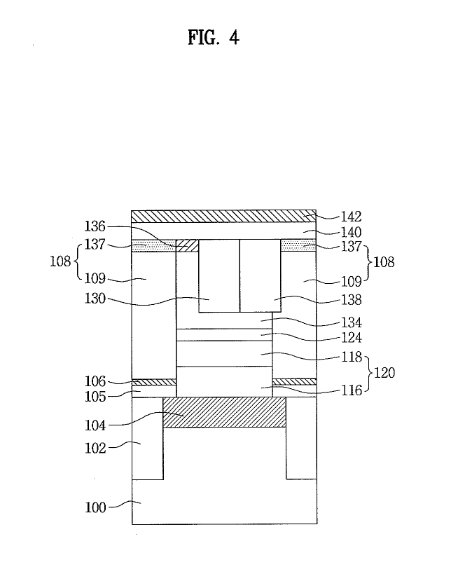

According to other example embodiments, referring to FIG. 4, the first insulating pattern 108 may include an upper part 137 and a lower part 109. The upper part 137 may be an oxide material or nitride material containing an element X. For example, the upper part 137 of the first insulating pattern 108 may be formed of silicon oxide material containing the element X or silicon nitride material containing the element X. The element X may include at least one selected from the group of silicon (Si), boron (B), aluminum (Al), oxygen (O), and carbon (C). The thickness and level of the upper part 137 may be substantially the same as those of a third structure 136 of the lower electrodes. The lower part 109 may be formed of, e.g., silicon oxide material or silicon nitride material. In addition, the lower part 109 may further include the buffer layer 105 and/or the etch stop layer 106.

The second insulating pattern 130 may be formed to be adjacent to the lower electrodes 124, 134, and 136, the first insulating pattern 108, and the third insulating pattern 138.

The third insulating pattern 138 may be founed adjacent to the lower electrodes 124, 134, and 136, the first insulating pattern 108 and the second insulating pattern 130. The shape of the lower electrodes 124, 134, and 136 may be determined depending on the depth and length of the third insulating pattern 138.

The lower electrodes 124, 134, and 136 may be electrically connected to the switching device 120. According to an example embodiment, when the switching device 120 is a diode 120, the lower electrodes 124, 134, and 136 may be formed on the diode 120, and the lower electrodes 124, 134, and 136 may be formed to be substantially in direct contact with the diode 120. According to another example embodiment, when the switching device 120 is a transistor, the lower electrodes 124, 134, and 136 may be formed to be electrically connected to the transistor through a connection pattern.

The lower electrodes 124, 134, and 136 may include a first structure 124 including a metal silicide, a second structure 134 including a metal nitride material, and a third structure 136 including a metal nitride material containing the element X. According to example embodiments, the first structure 124 may include titanium silicide (TiSi₂), the second structure 134 may include titanium nitride material (TiN), and the third structure 136 may include titanium nitride material (TiXN) containing the element X.

The first structure 124 may be formed to be electrically connected to the switching device 120. According to example embodiments, when the switching device 120 is a diode 120, the first structure 124 may be formed in contact with an upper part of the diode 120. Also, when viewed from a plan view, the first structure 124 may have a circular shape, and when viewed from a cross-sectional view, it may have a rectangular shape. The width of the first structure 124 may be substantially the same as that of the diode 120.

The second structure 134 may be formed on the first structure 124, and the width of its lower part may be greater than that of its upper part. The width of the lower part of the second structure 134 may be substantially the same as that of the first structure 124.

According to an example embodiment, the second structure 134 may include a lower part having a first width, and an upper part having a second with smaller than the first width. The upper part of the second structure 134 may vertically extend from a top surface of the lower part. For example, the second structure 134 may be in the shape of an “L”. In this case, the second structure 134 may include a first vertical surface V1 in contact with the first insulating pattern 108, a first horizontal surface H1 horizontally extending from a lower part of the first vertical surface V1, a second horizontal surface H2 horizontally extending from an upper part of the first vertical surface V1, a third horizontal surface H3 parallel to the second horizontal surface H2 and spaced apart a predetermined distance therefrom, a second vertical surface V2 connecting the second horizontal surface H2 to the third horizontal surface H3, and a third vertical surface V3 connecting the first horizontal surface H1 to the third horizontal surface H3.

According to another example embodiment, the second structure 134 may be in the shape of a “J”. According to still another example embodiment, the second structure 134 may be in the shape of a cylinder, a “U”, or a rectangle.

A third structure 136 may be formed on the second structure 134. For example, when the second structure 134 is in the shape of an “L”, the third structure 136 may be formed on the second horizontal surface H2 of the second structure 134. When viewed from a plan view, the third structure 136 may be in the shape of a semicircle, and when viewed from a cross-section, it may be in the shape of a rectangle. The width of the third structure 136 may be substantially the same as the second width.

The third structure 136 may be formed of a material having a higher resistance than the first structure 124 and the second structure 134. According to an example embodiment, the third structure 136 may have a single-layer structure. The third structure 136 may include titanium nitride material (TiXN) containing the element X, and the element X may include at least one selected from the group of Si, B, Al, O, and C.

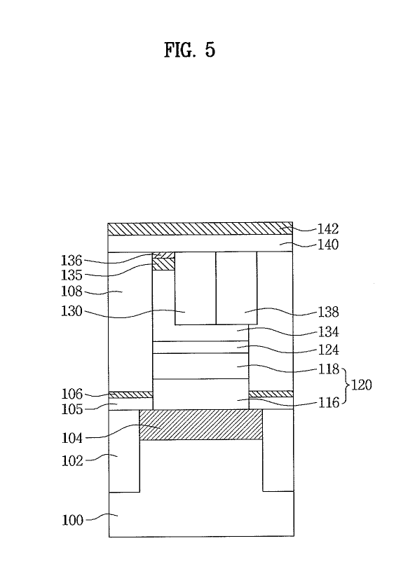

According to another example embodiment, as illustrated in FIG. 5, the third structure may have a multilayer structure in which a lower pattern 135 including titanium nitride material (TiXN) containing the element X, and an upper pattern 136 including titanium nitride material (TiYN) containing an element Y are stacked. The elements X and Y may be different from each other, and each of the elements X and Y may include at least one selected from the group of Si, B, Al, O, and C.

According to still another example embodiment, as illustrated in FIG. 6, the third structure may have a structure in which a lower pattern 135 including titanium oxide material (TiO₂), and an upper pattern 136 including titanium nitride material (TiXN) containing the element X are stacked. The element X may include at least one selected from the group of Si, B, Al, O, and C.

A phase-change material pattern 140 may be electrically connected to the lower electrodes 124, 134 and 136. According to example embodiments, the phase-change material pattern 140 may be formed on the lower electrodes 124, 134, and 136 and insulating patterns 108, 130, and 138. The phase-change material pattern 140 may be in direct contact with the lower pattern to be electrically connected thereto.

The phase-change material pattern 140 may be formed of, e.g., a chalcogenide including at least one of the Group VI materials of the periodic table. Chalcogenide-based metal elements may include Ge, Se, Sb, Te, Sn, and/or As. The combination of the elements may enable a chalcogenide phase-change pattern to be formed. For example, the combination may be at least one selected from the group of GaSb, InSb, InSe, Sb₂Te, SbSe, GeTe, Sb₂Te, SbSe, GeTe, Ge₂Sb₂Te₅, InSbTe, GaSeTe, SnSb₂Te, InSbGe, AgInSbTe, (GeSn)SbTe, GeSb(SeTe), and Te₈₁GeI₅Sb₂S₂. Further, in order to enhance characteristics of the phase-change material pattern 140, elements of Ag, In, Bi, and Pb, in addition to the combination of the chalcogenide-based metal elements, may be mixed.

An upper electrode 142 may be formed to be electrically connected to the phase-change material pattern 140. According to example embodiments, the upper electrode 142 may be in contact with the phase-change material pattern 140 to be electrically connected thereto. In an implementation, the width of the upper electrode 142 may be substantially the same as that of the phase-change material pattern 140. In another implementation, the width of the upper electrode 142 may be substantially different from that of the phase-change material pattern 140.

The upper electrode 142 may include at least one selected from the group of Ti, TiSi, TiN, TiON, TiW, TiAlN, TiAlON, TiSIN, TiBN, W, WN, WON, WSiN, WBN, WCN, Si, Ta, SaSi, TaN, TaON, TaAlN, TaSiN, TaCN, Mo, MoN, MoSiN, MoAlN, ZrSiN, ZrAlN, and RuCoSi.

A method of forming a semiconductor device illustrated in FIG. 3 will be described below.

FIGS. 7 to 16 illustrate schematic cross-sectional views of stages in a method of forming the phase-change memory device illustrated in FIG. 3.

Referring to FIG. 7, an isolation pattern 102 may be formed in a substrate 100.

A semiconductor substrate 100 such as a silicon wafer or an SOI wafer may be used as the substrate 100. The substrate 100 may include a first impurity. The first impurity may include at least one selected from the Group III elements or the Group V elements of the periodic table.

Describing a process of forming the isolation pattern 102 in further detail, a pad oxide layer (not shown) and a first mask (not shown) may be sequentially formed on the substrate 100. The pad oxide layer may include a silicon oxide layer and may be formed by, e.g., a thermal oxidation process. The first mask may have a structure in which a nitride pattern and a photoresist pattern are sequentially stacked. The first mask may be used as an etch mask to etch the pad oxide layer and the substrate 100, so that a pad oxide pattern and a trench may be formed. Selectively, a liner including silicon oxide material and silicon nitride material may be formed along a surface profile of an inner surface of the trench. An isolation layer filling the trench may be formed, so that the isolation pattern 102, i.e., a field region, may be formed. The field region may define an active region, e.g., the active region may be in the shape of a line extending in a first direction.

Afterwards, a word line 104 may be formed in the active region of the substrate 100. The word line 104 may extend in the first direction substantially the same as the extension direction of the active region. The word line 104 may include impurity-doped silicon, a metal, or a metal compound. According to example embodiments of the inventive concept, the word line 104 may be formed by implanting a second impurity different from the first impurity into the active region.

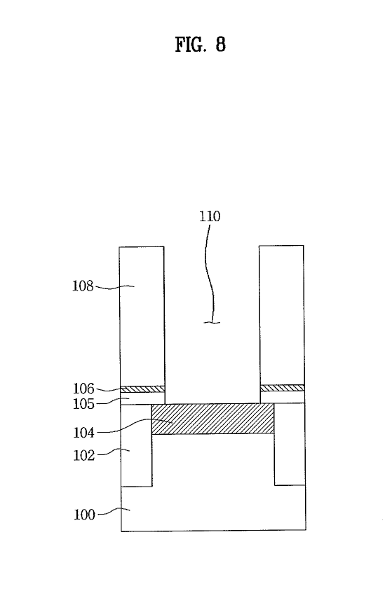

Referring to FIG. 8, a first insulating pattern 108 may be formed on the substrate 100 in which the word line 104 and the isolation pattern 102 are formed. While the first insulating pattern 108 is formed, a first opening 110 exposing an upper part of the word line 104 may be formed.

For example, a first insulating layer may be formed on the substrate 100 where the word line 104 and the isolation pattern 102 are formed. The first insulating layer may be formed to cover the entire surface of the substrate 100. In an implementation, the first insulating layer may be formed of a single layer made of, e.g., an oxide layer, a nitride layer, or an oxynitride layer. The oxide layer, the nitride layer, and the oxynitride layer may be a silicon oxide layer, a silicon nitride layer, and a silicon oxynitride layer, respectively. In another implementation, the insulating layer may be formed of a multilayer in which at least one oxide layer, at least one nitride layer, and/or at least one oxynitride layer are sequentially or alternately stacked.

The first insulating layer may be formed using, e.g., chemical vapor deposition (CVD), low pressure CVD (LPCVD), plasma enhanced CVD (PECVD), or high density plasma CVD (HDP CVD).

According to example embodiments, before forming the first insulating layer, the buffer layer 105 and the etching stop layer 106 may be sequentially formed on the substrate 100 where the isolation pattern 102 and the word line 104 are formed. The etching stop layer 106 may include a material having an etch selectivity with respect to the buffer layer 105 and the insulating layer. For example, when the insulating layer and the buffer layer 105 include silicon oxide material, the etching stop layer 106 may include silicon nitride material.

A second mask (not shown) may be formed on the first insulating layer. The second mask may include a material having an etch selectivity with respect to the first insulating layer. For example, the second mask may include a nitride pattern.

The first insulating layer may be etched using the second mask as an etch mask to form the first insulating pattern 108. The first insulating pattern 108 may cover a part of the word line 104 and the isolation pattern 102 to partially expose the word line 104. While the first insulating pattern 108 is formed, a first opening 110 partially exposing the word line 104 may be formed.

According to example embodiments, when the buffer layer 105 and the etching stop layer 106 are formed on the substrate 100, the buffer layer 105 and the etching stop layer 106 may be etched as well while the first insulating layer is etched, so that the buffer pattern 105 and the etch stop pattern 106 may be formed.

After the first insulating pattern 108 is fondled, the second mask may be removed from the substrate 100. The removal process may be carried out using an ashing process and a strip process.

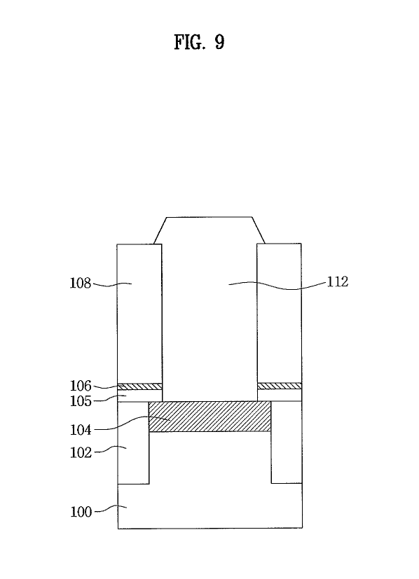

Referring to FIG. 9, a semiconductor layer 112 may be formed on the substrate 100 on which the first insulating pattern 108 and the word line 104 are formed. The semiconductor layer 112 may include, e.g., single crystalline silicon, amorphous silicon, or polysilicon.

According to an example embodiment, the semiconductor layer 112 may be formed by employing a selective epitaxial growth (SEG) technique using the word line 104 as a seed. When the word line 104 includes impurity-doped silicon, the semiconductor layer 112 may include silicon as well. According to another example embodiment, the semiconductor layer 112 may be formed using a solid phase epitaxial growth (SPEG) technique.

In an implementation, the semiconductor layer 112 may be formed to fully fill the first opening 110. In another implementation, the semiconductor layer 112 may be formed to partially fill a lower part of the first opening 110.

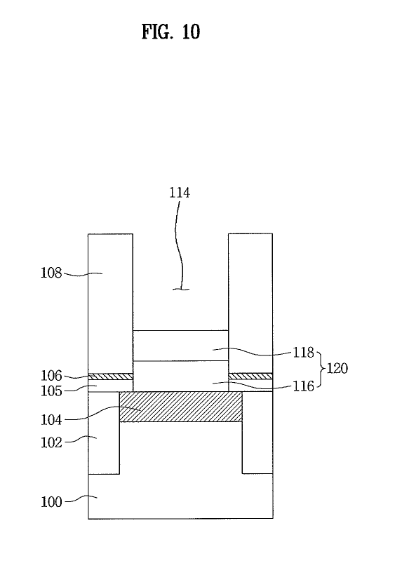

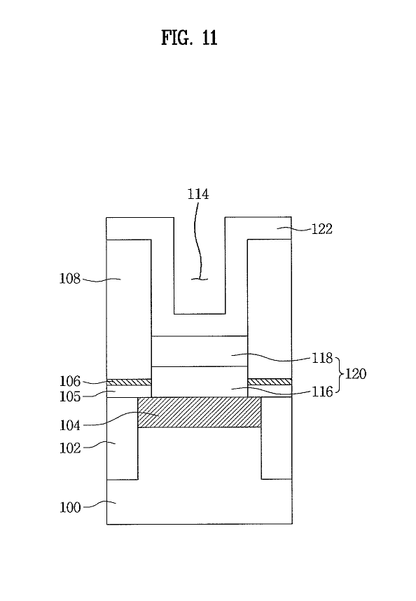

Referring to FIG. 10, the switching device 120 electrically connected to the word line 104 may be formed. According to example embodiments, the switching device 120 may be a diode.

Describing the process of forming the diode 120 in detail, first, when the semiconductor layer 112 fully fills the first opening 110, an upper part of the semiconductor layer 112 may be partially etched to form the semiconductor layer 112 partially filling a lower part of the first opening 110. A second opening 114 defined by the semiconductor layer 112 and the first insulating pattern 108 may be formed. The second opening 114 may have substantially the same width as the first opening 110, and may have a bottom surface on a higher level than that of the first opening (see 110 of FIG. 1).

Afterwards, an ion implantation and diffusion process may be employed to form a first semiconductor pattern 116 doped with a third impurity and a second semiconductor pattern 118 doped with a fourth impurity. The third impurity may be different from the second impurity, and may be substantially the same as the first impurity. Also, the fourth impurity may be substantially different from the third impurity, and may be substantially the same as the second impurity.

As a result, the diode 120, in which the first semiconductor pattern 116 and the second semiconductor pattern 118 are sequentially stacked, may be formed in the first opening 110.

Referring to FIG. 11, a first metal layer 122 may be formed on the switching device 120 and the first insulating pattern 108. The first metal layer 122 may include Ti. The first metal layer 122 may be serially formed along surface profiles of the switching device 120 and the first insulating pattern 108, and may be conformally formed without filling the second opening 114.

The first metal layer 122 may be formed by using, e.g., the PECVD process using titanium chloride (TiCl₄) as a source.

According to example embodiments, while the first metal layer 122 is formed, an upper part of the switching device 120 including the silicon and a lower part of the first metal layer 122 may be converted into titanium silicide (TiSi₂). That is, TiSi₂ may be formed at an interface of the switching device 120 and the first metal layer 122.

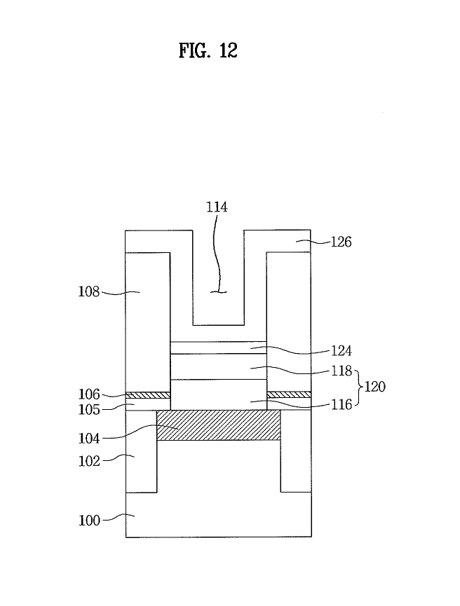

Referring to FIG. 12, a nitriding process may be performed on the substrate 100 on which the first metal layer 122 is formed, so that a first structure 124 including a metal semiconductor compound and a second preliminary structure 126 including a metal nitride material may be formed on the switching device 120.

The first structure 124 may include TiSi₂, and the second preliminary structure 126 may include titanium nitride material (TiN).

According to example embodiments, the nitriding process may employ, e.g., a thermal or plasma treatment using ammonia (NH₃) or nitrogen (N₂) gas as a source. While the nitriding process is performed, the lower part of the first metal layer 122 in contact with the switching device 120 may be converted into the first structure 124 including TiSi₂. When viewed from a plan view, the first structure 124 may have a circular shape, and when viewed from a cross-sectional view, it may have a rectangular shape.

Further, while the nitriding process is performed, the upper part of the first metal layer 122 may be combined with ammonia or nitrogen of the nitrogen gas to be converted into the second preliminary structure 126 including TiN. The second preliminary structure 126 may be serially formed along surface profiles of the first structure 124 and the first insulating pattern 108, and may be conformally formed without filling the second opening 114.

According to other example embodiments (not shown), after the second preliminary structure 126 is formed, a second metal layer may be further formed on the second preliminary structure 126. The second metal layer may be serially formed along a surface profile of the second preliminary structure 126, and may be conformally formed without filling the second opening 114. The second metal layer may be formed using, e.g., the PECVD process using TiCl₄ as a source. The process of forming the second metal layer may be omitted.

According to an example embodiment, the process of forming the first metal layer 122, and the process of forming the first structure 124 and the second preliminary structure 126 may be performed in substantially the same in-situ chamber. According to another example embodiment, the process of forming the first metal layer 122, and the process of forming the first structure 124 and the second preliminary structure 126, may be performed in different in-situ chambers.

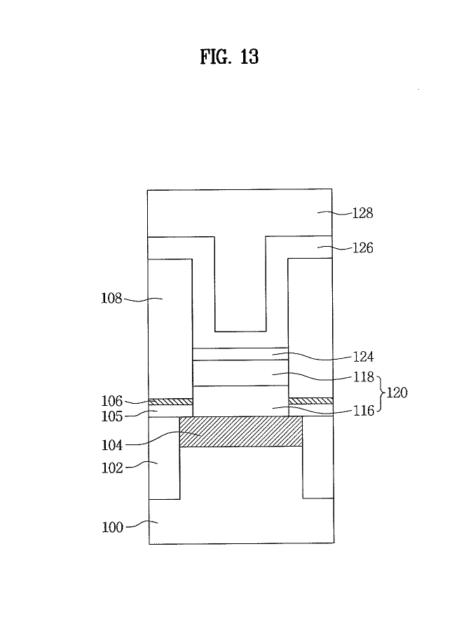

Referring to FIG. 13, a second insulating layer 128 may be formed on the second preliminary structure 126. The second insulating layer 128 may be formed to fully fill the second opening 114.

The second insulating layer 128 may be formed of an oxide material, a nitride material, or an oxynitride material. For example, these may be silicon oxide material, silicon nitride material, or silicon oxynitride material, respectively. In an implementation, the second insulating layer 128 may include substantially the same material as the first insulating layer. In another implementation, the second insulating layer 128 may include a material substantially different from the first insulating layer.

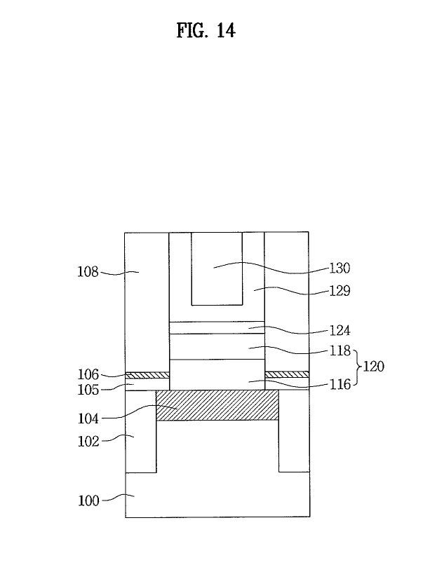

Referring to FIG. 14, the second insulating layer 128 and the second preliminary structure (refer to 126 of FIG. 13) may be partially etched to expose a top surface of the first insulating pattern 108, so that a second insulating pattern 130 may be formed. According to example embodiments, the second preliminary structure 129 may have a structure in the shape of a “U”.

The second insulating layer 128 and the second preliminary structure (refer to 126 of FIG. 13) may be partially etched using, e.g., a chemical mechanical polishing (CMP) process and an etch-back process. Top surfaces of the second insulating pattern 130 and the second preliminary structure 129 in the shape of a “U” formed by the above process may have substantially the same level as that of the first insulating pattern 108.

According to other example embodiments, upper parts of the first insulating pattern 108, the second preliminary structure 129 in the shape of a “U”, and the second insulating pattern 130 may be further etched. Further etched upper parts of the first insulating pattern 108, the second insulating pattern 130, and the second preliminary structure 129 in the shape of a “U” may be formed on substantially the same level.

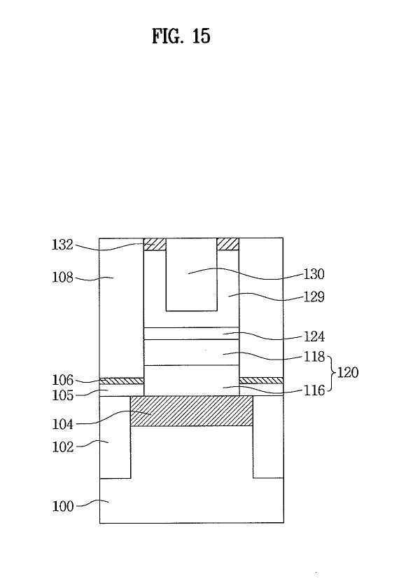

Referring to FIG. 15, a third preliminary structure 132 including a metal nitride material including the element X may be formed in the second preliminary structure 129. The third preliminary structure 132 may include, e.g., titanium nitride material (TiXN).

The element X may include at least one selected from the group of Si, B, Al, O, and C.

According to example embodiments, the process of forming the third preliminary structure 132 will be described in further detail. A thermal or plasma thermal treatment using a first precursor including nitrogen and a second precursor including the element X may be performed on the substrate 100 on which the third preliminary structure 132 in the shape of a “U” is formed. The first precursor may include NH₃ or N₂, and the element X of the second precursor may include at least one selected from the group of Si, B, Al, O, and C.

When the element X is silicon, the second precursor may include, e.g., at least one selected from the group of SiH₄, Si₂H₆, Si₃H₈, SiCl₂H₂, and bis(tertiary-butylamino)silane (BTBAS).

When the element X is boron, the second precursor may include, e.g., at least one selected from the group of B₂H₆ and triethylborate (TEB).

When the element X is aluminum, the second precursor may include, e.g., at least one selected from the group of AlCl₃, tetra ethyl methyl amide hafnium (TEMAH), dimethyl aluminum hydride (DMAH), and dimethylethylamine alane (DMEAA).

When the element X is oxygen, the second precursor may include, e.g., at least one selected from the group of oxygen (O₂) gas and ozone (O₃) gas.

When the element X is carbon, the second precursor may include, e.g., C₂H₄.

While the thermal or plasma thermal treatment using the first and second precursors is performed, an upper part of the second preliminary structure 129 in the shape of a “U” may be converted into titanium nitride material (TiXN) including the element X, so that the third preliminary structure 132 may be formed on the second preliminary structure 129.

According to an example embodiment, before performing the thermal or plasma thermal treatment using the first and second precursors, a third mask (not shown) may be further formed on the first insulating pattern 108 and the second insulating pattern 130. The third mask may function to protect the first insulating pattern 108 and the second insulating pattern 130 while the thermal or plasma thermal treatment is performed. Moreover, the third mask may be removed from the substrate 100 after completing the thermal or plasma thermal treatment.

Referring to FIG. 4 according to other example embodiments, while the thermal or plasma thermal treatment using the first and second precursors is performed, upper parts of the first insulating pattern 108 and the second insulating pattern 130 may be converted into a silicon nitride material (SiXN) including the element X.

According to example embodiments, while the thermal or plasma thermal treatment using the first and second precursors is performed, a third precursor including titanium (Ti) may be further injected. In such a case, the generated results may be the third preliminary structure 132 including titanium nitride materials containing the element X on the second preliminary structure 129 in the shape of a “U”. A content of Ti of the third preliminary structure 132 may be higher.

The semiconductor device illustrated in FIG. 5 according to other example embodiments may further include a fourth preliminary structure (not shown) including titanium nitride material containing an element Y on the third preliminary structure 132. The element Y may include, e.g., at least one selected from the group of Si, B, Al, O, and C. The fourth preliminary structure may be formed using substantially the same process as that of forming the third preliminary structure 132. Further, the fourth preliminary structure may be formed in substantially the same in-situ chamber as the chamber in which the third structure 136 is formed.

In the device illustrated in FIG. 6 according to still another example embodiment, before forming the third preliminary structure 132, a fourth preliminary structure (not shown) including titanium oxide material (TiO₂) may be further formed on the second preliminary structure 129 in the shape of a “U”. The fourth preliminary structure may be formed in substantially the same in-situ chamber as the chamber in which the third structure 136 is formed.

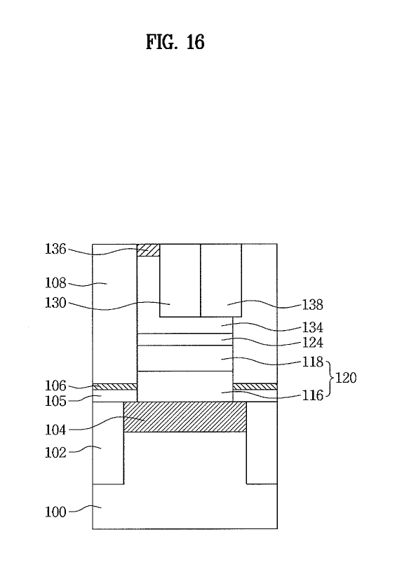

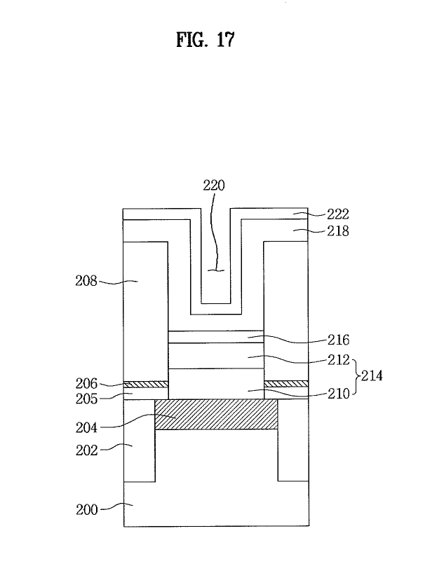

Referring to FIG. 16, a fourth mask (not shown) may be formed on the first insulating pattern 108, the second insulating pattern 130, and the third preliminary structure 132. The fourth mask may be formed to partially cover the third preliminary structure 132. The fourth mask may include a material having an etch selectivity with respect to the first insulating pattern 108, the second insulating pattern 130, the second preliminary structure 129 in the shape of a “U”, and the third preliminary structure 132.

The third preliminary structure 132, the second preliminary structure 129 in the shape of a “U”, the first insulating pattern 108, and the second insulating pattern 130 may be partially etched using the fourth mask as an etch mask, so that a third structure 136 and a second structure 134 may be formed. The second structure 134 may have an “L” or “J” shape depending on an etch depth and a location of the fourth mask.

The second structure 134 according to an example embodiment may be in the shape of an “L”. In this case, the second structure 134 may include a lower part having a first width and an upper part having a second width. The first width may be substantially greater than the second width. The second structure 134 may include a first vertical surface V1 in contact with the first insulating pattern 108, a first horizontal surface H1 horizontally extending from a lower part of the first vertical surface V1, a second horizontal surface H2 horizontally extending from an upper part of the first vertical surface V1, a third horizontal surface H3 parallel to the second horizontal surface H2 and spaced apart a predetermined space therefrom, a second vertical surface V2 connecting the second horizontal surface H2 to the third horizontal surface H3, and a third vertical surface V3 connecting the first horizontal surface H1 to the third horizontal surface H3. The third structure 136 may be formed on the second horizontal surface H2.

During the etching process using the fourth mask, a third opening (not shown) may be foimed by the first insulating pattern 108, the second insulating pattern 130, and the second structure 134. A third insulating layer (not shown) may be formed on the first insulating pattern 108, the second insulating pattern 130, and the second structure 134. The third insulating layer may be formed of an oxide material, nitride material, or oxynitride material, which may be silicon oxide material, silicon nitride material, and silicon oxynitride material, respectively.

An upper part of the third insulating layer may be removed to expose upper parts of the first insulating pattern 108, the second insulating pattern 130, and the third structure 136. The removal process may be performed by, e.g., a polishing process and an etch-back process. The upper parts of the first insulating pattern 108, the second insulating pattern 130, the first insulating pattern 138, and the third structure 136 may have substantially the same level.

According to example embodiments, the upper parts of the first insulating pattern 108, the second insulating pattern 130, the first insulating pattern 138, and the third structure 136 may be further etched. The further etched upper parts of the first insulating pattern 108, the second insulating pattern 130, the first insulating pattern 138, and the third structure 136 may have substantially the same level.

Referring back to FIG. 3, a phase-change material layer may be formed on the first insulating pattern 108, the second insulating pattern 130, the first insulating pattern 138, and the third structure 136. The phase-change material layer (not shown) may be formed to be electrically connected to the third structure 136.

The phase-change material layer may be formed of, e.g., a chalcogenide including at least one of the Group VI elements of the periodic table. A typical example of a chalcogenide-based metal element may include Ge, Se, Sb, Te, Sn, As, etc. A combination of the elements may enable a chalcogenide phase-change pattern to be formed. The combination may include, e.g., at least one selected from the group of GaSb, InSb, InSe, Sb₂Te, SbSe, GeTe, Sb₂Te, SbSe, GeTe, Ge₂Sb₂Te₅, InSbTe, GaSeTe, SnSb₂Te, InSbGe, AgInSbTe, (GeSn)SbTe, GeSb(SeTe), and Te₈₁GeI₅Sb₂S₂. Moreover, in order to enhance characteristics of the phase-change material layer, elements of Ag, In, Bi, and Pb, in addition to the combination of the chalcogenide-based metal elements, may be mixed.

A conductive layer (not shown) may be formed on the phase-change material layer. The conductive layer may be formed to be electrically connected to the phase-change material layer.

The conductive layer may include, e.g., at least one selected from the group of Ti, TiSi, TiN, TiON, TiW, TiAlN, TiAlON, TiSiN, TiBN, W, WN, WON, WSiN, WBN, WCN, Si, Ta, SaSi, TaN, TaON, TaAlN, TaSiN, TaCN, Mo, MoN, MoSiN, MoAlN, ZrSiN, ZrAlN, and RuCoSi.

Afterwards, the conductive layer and the phase-change material layer may be partially etched to sequentially form a phase-change material and an upper electrode 142 on the first insulating pattern 108, the second insulating pattern 130, the first insulating pattern 138, and the third structure 136.

While it is not illustrated in detail, a bit line BL may be further formed on the upper electrode 142.

### Second Example Embodiment

FIG. 18 illustrates a schematic cross-sectional view of a phase-change memory device according to yet another example embodiment.

Referring to FIG. 18, the memory device may include a word line 204 formed on a substrate, a switching device 214, insulating patterns 208, 224, and 228, lower electrodes 216, 226, and 230, a phase-change material pattern 232, and an upper electrode 234. The insulating patterns 208, 224, and 228 may include a first insulating pattern 208, a second insulating pattern 224, and a third insulating pattern 228.

The substrate, the word line 204, the switching device 214, the insulating patterns 208, 224, and 228, the phase-change material pattern 232 and the upper electrode 234 may be substantially the same as those described with reference to FIG. 1, and thus detailed descriptions thereof will not be repeated.

The lower electrodes 216, 226, and 230 may be electrically connected to the switching device 214. According to an example embodiment, when the switching device 214 is a diode 214, the lower electrodes 216, 226, and 230 may be formed on the diode 214, and the lower electrodes 216, 226, and 230 may be formed to be substantially in direct contact with the diode 214. According to another example embodiment, when the switching device 214 is a transistor, the lower electrodes 216, 226, and 230 may be formed to be electrically connected to the transistor by a connection pattern.

The lower electrodes 216, 226, and 230 may include a first structure 216 including a metal semiconductor compound, a second structure 226 including a metal nitride material, and a third structure 230 including a metal nitride material containing an element X. According to example embodiments, the first structure 216 may include titanium silicide (TiSi₂), the second structure 226 may include TiN, and the third structure 230 may include titanium nitride material (TiXN) containing the element X.

The first structure 216 may be formed to be electrically connected to the switching device 214. According to example embodiments, when the switching device 214 is a diode 214, the first structure 216 may be formed in contact with an upper part of the diode 214. Also, when viewed from a plan view, the first structure 216 may have a circular shape, and when viewed from a cross-sectional view, it may have a rectangular shape. The width of the first structure 216 may be substantially the same as that of the diode 214.

The second structure 226 may be formed on the first structure 216, and its lower part may have a greater width than its upper part. The width of the lower part of the second structure 226 may be substantially the same as that of the first structure 216.

According to an example embodiment, the second structure 226 may include a lower part having a first width, and an upper part having a second width smaller than the first width. The upper part of the second structure 226 may vertically extend from a top surface of the lower part. For example, it may have an “L” shape. When the second structure 226 is in the shape of an “L”, the second structure 226 may include a lower part having a first width and an upper part having a second width. The first width may be substantially greater than the second width. In this case, the second structure 226 may include a first vertical surface V1 in contact with the first insulating pattern 208, a first horizontal surface H1 horizontally extending from a lower part of the first vertical surface V1, a second horizontal surface H2 horizontally extending from an upper part of the first vertical surface V1, a third horizontal surface H3 parallel to the second horizontal surface H2 and spaced apart a predetermined space therefrom, a second vertical surface V2 connecting the second horizontal surface H2 to the third horizontal surface H3, and a third vertical surface V3 connecting the first horizontal surface H1 to the third horizontal surface H3.

According to another example embodiment, the second structure 226 may be in the shape of a “J”. According to still another example embodiment, the second structure 226 may be in the shape of a circle, a “U”, or a rectangle.

The third structure 230 may be formed on the second structure 226. For example, when the second structure 226 is in the shape of an “L”, the third structure 230 may be formed on the second vertical surface V2 and the third horizontal surface H3 of the second structure 226. The third structure 230 may be in the shape of an “L”. The thickness of the third structure 230 may be substantially smaller than that of the second structure 226.

The third structure 230 may be formed of a material having a higher resistance than the first structure 216 and the second structure 226. According to an example embodiment, the third structure 230 may have a single-layer structure. The third structure 230 may include a metal nitride material including the element X, e.g., titanium nitride material (TiXN) containing the element X. The element X may include at least one selected from the group of Si, B, Al, O, and C.

According to another example embodiment, as illustrated in FIG. 5, the third structure 230 may have a multilayer structure in which a lower pattern including a titanium nitride material (TiXN) containing the element X and an upper pattern including titanium nitride material (TiYN) containing an element Y are stacked. The elements X and Y may be different from each other, and each may include at least one selected from the group of Si, B, Al, O, and C.

According to still another example embodiment, as illustrated in FIG. 6, the third structure 230 may have a structure in which a lower pattern including titanium oxide material (TiO₂) and an upper pattern including titanium nitride material (TiXN) containing the element X are stacked. The element X may include at least one selected from the group of Si, B, Al, O, and C.

A method of forming a semiconductor device illustrated in FIG. 18 will be described below.

FIGS. 7 to 12 and 17 illustrate schematic cross-sectional views of stages in a method of forming a semiconductor device illustrated in FIG. 18.

Referring to FIGS. 7 to 12, an isolation pattern 202, a word line 204, a first insulating pattern 208, and a switching device 214 may be formed on the substrate 200, and a first structure 216 including titanium silicide and a second preliminary structure 218 including titanium nitride material may be formed.

The process of forming the isolation pattern 202, the word line 204, the first insulating pattern 208, the switching device 214, the first structure 216, and the second preliminary structure 218 may be substantially the same as that described with reference to FIGS. 7 to 12 of the first example embodiment, and thus the description thereof will not be repeated.

Referring to FIG. 17, a third preliminary structure 222 including a metal nitride material containing the element X may be formed on the second preliminary structure 218. The third preliminary structure 222 may include, e.g., titanium nitride material (TiXN). The element X may include at least one selected from the group of Si, B, Al, O, and C.

The third preliminary structure 222 may be serially formed along a surface profile of the second preliminary structure 218. The third preliminary structure 222 may be confoimally formed not to fill a first opening 220 defined by the second preliminary structure 218.

According to example embodiments, the process of forming the third preliminary structure 222 will be described in further detail. A thermal or plasma thermal treatment using a first precursor including nitrogen and a second precursor including the element X may be performed on the substrate 200 on which the second preliminary structure 218 is formed. The first precursor may include, e.g., NH₃ or N₂, and the element X of the second precursor may include, e.g., at least one selected from the group of Si, B, Al, O, and C.

When the element X is silicon, the second precursor may include, e.g., at least one selected from the group of SiH₄, Si₂H₆, Si₃H₈, SiCl₂H₂, and BTBAS.

When the element X is boron, the second precursor may include, e.g., at least one selected from the group of B₂H₆ and TEB.

When the element X is aluminum, the second precursor may include, e.g., at least one selected from the group of AlCl₃, TEMAH, DMAH, and DMEAA.

When the element X is oxygen, the second precursor may include, e.g., at least one selected from the group of O₂ gas and O₃ gas.

When the element X is carbon, the second precursor may include, e.g., C₂H₄.

While the thermal or plasma thermal treatment using the first and second precursors is performed, an upper part of the second preliminary structure 218 may be converted into titanium nitride material (TiXN) including an element X, so that a third preliminary structure 222 may be formed on the second preliminary structure 218.

According to example embodiments, while the thermal or plasma thermal treatment using the first and second precursors is perfoimed, a third precursor including Ti may be further injected. In such a case, the generated results may be a third preliminary structure 222 including a titanium nitride material containing an element X on the second preliminary structure 218. A content of Ti of the third preliminary structure 222 may be higher.

According to another example embodiment, a fourth preliminary structure (not shown) including titanium nitride material containing an element Y may be further formed on the third preliminary structure 222. The fourth preliminary structure may be serially formed along a surface profile of the third preliminary structure 222. The fourth preliminary structure may be conformally formed without filling the first opening 220. The element Y may include, e.g., at least one selected from the group of Si, B, Al, O, and C. The fourth preliminary structure may be formed using substantially the same process as that forming the third preliminary structure 222. Further, the fourth preliminary structure may be formed in substantially the same in-situ chamber as the chamber in which the third preliminary structure 222 is formed.

According to still another example embodiment, before forming the third preliminary structure 222, a fourth preliminary structure (not shown) including titanium oxide material (TiO₂) may be further formed on the second preliminary structure. The fourth preliminary structure may be formed in substantially the same in-situ chamber as the chamber in which the third preliminary structure 222 is formed.

Referring back to FIG. 18, a second insulating layer (not shown) may be formed on the third preliminary structure 222. The second insulating layer may be formed to fully fill the second opening 220.

The second insulating layer, the third preliminary structure 222 and the second preliminary structure 218 may be partially etched to expose a top surface of the first insulating pattern 208, so that a second insulating pattern 224, a third preliminary structure (not shown) in the shape of a “U”, and a second preliminary structure (not shown) in the shape of a “U” may be formed.

Parts of the second insulating layer, the third preliminary structure 222 and the second preliminary structure 218 may be etched, e.g., using a CMP process and an etch-back process. Top surfaces of the second insulating pattern 224, the third preliminary structure in the shape of a “U”, and the second preliminary structure in the shape of a “U” formed by the above process may have the height substantially the same level as a top surface of the first insulating pattern 208.

According to other example embodiments, upper parts of the first insulating pattern 208, the second insulating structure 224, the second preliminary structure in the shape of a “U”, and the third preliminary structure in the shape of a “U” may be further etched. The further etched upper parts of the first insulating pattern 208, the second insulating structure 224, the second preliminary structure in the shape of a “U”, and the third preliminary structure in the shape of a “U” may be formed on substantially the same level.

A mask (not shown) may be formed on the first insulating pattern 208, the second insulating structure 224, the second preliminary structure in the shape of a “U”, and the third preliminary structure in the shape of a “U”. The mask may be formed to partially cover the second preliminary structure in the shape of a “U” and the third preliminary structure in the shape of a “U”. The second preliminary structure in the shape of a “U” and the third preliminary structure in the shape of a “U”, the first insulating pattern 208, and the second insulating structure 224 may be partially etched using the mask as an etch mask, so that a third structure 230 and a second structure 226 may be formed. The second structure 226 and the third structure 230 may be in the shape of an “L” or a “J”, depending on an etch depth and a location.

The second structure 226 according to an example embodiment may be in the shape of an “L.” In this case, the second structure 226 may include a lower part of a first width and an upper part of a second width. The first width may be substantially greater than the second width. The second structure 226 may include a first vertical surface V1 in contact with the first insulating pattern 208, a first horizontal surface H1 horizontally extending from a lower part of the first vertical surface V1, a second horizontal surface H2 horizontally extending from an upper part of the first vertical surface V1, a third horizontal surface H3 parallel to the second horizontal surface H2 and spaced apart a predetermined space therefrom, a second vertical surface V2 connecting the second horizontal surface H2 to the third horizontal surface H3, and a third vertical surface V3 connecting the first horizontal surface H1 to the third horizontal surface H3.

In such a case, the third structure 230 may be in the shape of an “L” as well. For example, the third structure 230 may be formed on the second vertical surface V2 and the third horizontal surface H3 of the second structure 226.

During the etching process using the mask, a second opening (not shown) may be formed by the first insulating pattern 208, the second insulating pattern 224, the second structure 226, and the third structure 230. A third insulating layer (not shown) may be formed on the first insulating pattern 208, the second insulating pattern 224, the second structure 226, and the third structure 230 to fill the second opening. The third insulating layer may be formed of an oxide material, nitride material, or oxynitride material, which may be silicon oxide material, silicon nitride material, and silicon oxynitride material, respectively.

An upper part of the third insulating layer may be removed to expose upper parts of the first insulating pattern 208, the second insulating pattern 224, the second structure 226, and the third structure 230. The removal process may be performed by, e.g., a polishing process and an etch-back process. The upper parts of the first insulating pattern 208, the second insulating pattern 224, the third insulating pattern 228, the second structure 226, and the third structure 230 may have substantially the same level.

According to example embodiments, the upper parts of the first insulating pattern 208, the second insulating pattern 224, the third insulating pattern 228, the second structure 226, and the third structure 230 may be further etched. The further etched upper parts of the first insulating pattern 208, the second insulating pattern 224, the third insulating pattern 228, the second structure 226, and the third structure 230 may have substantially the same level.

A phase-change material layer may be formed on the first insulating pattern 208, the second insulating pattern 224, the third insulating pattern 228, the second structure 226, and the third structure 230. The phase-change material layer (not shown) may be formed to be electrically connected to the second structure 226 and the third structure 230.

A conductive layer (not shown) may be formed on the phase-change material layer. The conductive layer may be formed to be electrically connected to the phase-change material layer.

The conductive layer and the phase-change material layer may be partially etched, so that a phase-change material pattern 232 and an upper electrode 234 may be sequentially formed on the first insulating pattern 208, the second insulating pattern 224, the third insulating pattern 228, the second structure 226, and the third structure 230.

While it is not illustrated in detail, a bit line BL may be further formed on the upper electrode 234.

### Third Example Embodiment

FIG. 20 illustrates a schematic cross-sectional view of a phase-change memory device according to yet another example embodiment.

Referring to FIG. 20, the memory device may include a word line 304 formed in a substrate 300, a switching device 314, insulating patterns 308, 324, and 328, lower electrodes 316, 324, and 326, a phase-change material pattern 330, and an upper electrode 332. The insulating patterns 308, 322, and 328 may include a first insulating pattern 308, a second insulating pattern 322, and a third insulating pattern 328.

The substrate 300, the word line 304, the switching device 314, the insulating patterns 308, 322, and 328, the phase-change material pattern 330, and the upper electrode 332 may be substantially the same as those described with reference to FIG. 1, and thus detailed descriptions thereof will not be repeated.

The lower electrodes 316, 324, and 326 may be electrically connected to the switching device 314. According to an example embodiment, when the switching device 314 is a diode 314, the lower electrodes 316, 324, and 326 may be formed on the diode 314, and the lower electrodes 316, 324, and 326 may be formed to be substantially in direct contact with the diode 314. According to another example embodiment, when the switching device 314 is a transistor, the lower electrodes 316, 324, and 326 may be formed to be electrically connected to the transistor by a connection pattern.

The lower electrodes 316, 324, and 326 may include a first structure 316 including a metal semiconductor compound, a second structure 324 including a metal nitride material, and a third structure 326 including a metal nitride material containing an element X. According to example embodiments, the first structure 316 may include titanium silicide (TiSi₂), the second structure 324 may include TiN, and the third structure 326 may include titanium nitride material (TiXN) containing the element X.

The first structure 316 may be electrically connected to the switching device 314. According to example embodiments, when the switching device 314 is a diode 314, the first structure 316 may be formed in contact with an upper part of the diode 314. Also, when viewed from a plan view, the first structure 316 may have a circular shape, and when viewed from a cross-sectional view, it may have a rectangular shape. The width of the first structure 316 may be substantially the same as that of the diode 314.

The second structure 324 may be formed on the first structure 316, and its lower part may have a greater width than its upper part. The width of the lower part of the second structure 324 may be substantially the same as that of the first structure 316.

According to example embodiments, the second structure 324 may include a lower part having a first width and an upper part having a second width smaller than the first width. The upper part of the second structure 324 may vertically extend from a top surface of the lower part. For example, the second structure 324 may be in the shape of an “L”. When the second structure 324 is in the shape of an “L,” the second structure 324 may have a lower part of a first width and an upper part of a second width. The first width may be greater than the second width. In this case, the second structure 324 may include a first vertical surface V1 in contact with the first insulating pattern 308, a first horizontal surface H1 horizontally extending from a lower part of the first vertical surface V1, a second horizontal surface H2 horizontally extending from an upper part of the first vertical surface V1, a third horizontal surface H3 parallel to the second horizontal surface H2 and spaced apart a predetermined space therefrom, a second vertical surface V2 connecting the second horizontal surface H2 to the third horizontal surface H3, and a third vertical surface V3 connecting the first horizontal surface H1 to the third horizontal surface H3.

According to another example embodiment, the second structure 324 may be in the shape of a “J”. According to still another example embodiment, the second structure 324 may be in the shape of a circle, a “U”, or a rectangle.

The third structure 326 may be formed on the second structure 324. More specifically, when the second structure 324 is in the shape of an “L”, the third structure 326 may be formed on the second horizontal surface H2, the second vertical surface V2, and the third horizontal surface H3 of the second structure 324. The thickness of the third structure 326 may be substantially smaller than that of the second structure 324.

The third structure 326 may be formed of a material having a higher resistance than the first structure 316 and the second structure 324. According to an example embodiment, the third structure 326 may have a single-layer structure. The third structure 326 may include a metal nitride material containing the element X, e.g., titanium nitride material containing the element X. The element X may include at least one selected from the group of Si, B, Al, O, and C.

According to another example embodiment, the third structure 326 may have a multilayer structure in which a lower pattern including titanium nitride material containing the element X, and an upper pattern including titanium nitride material containing an element Y are stacked. The elements X and Y may be different from each other, and each of the elements X and Y may include at least one selected from the group of Si, B, Al, O, and C.

According to yet another example embodiment, the third structure 326 may have a structure in which a lower pattern including titanium oxide material (TiO₂), and an upper pattern including titanium nitride material containing the element X are stacked. The element X may include at least one selected from the group of Si, B, Al, O, and C.

A method of forming a semiconductor device illustrated in FIG. 20 will be described below.

FIGS. 7 to 16 and 19 illustrate schematic cross-sectional views of stages in a method of forming a semiconductor device illustrated in FIG. 20.

Referring to FIGS. 7 to 12, an isolation pattern 302, a word line 304, a first insulating pattern 308, and a switching device 314 may be formed on the substrate 300, and a first structure 316 including titanium silicide and a second preliminary structure 318 including titanium nitride material may be formed.

The process of forming the isolation pattern 302, the word line 304, the first insulating pattern 308, the switching device 314, the first structure 316, and the second preliminary structure 318 may be substantially the same as that described with reference to FIGS. 7 to 12 of the first example embodiment, and thus the descriptions thereof will not be repeated.

A sacrificial layer (not shown) may be formed on the second preliminary layer 318. The sacrificial layer may be formed to fill a first opening (not shown) defined by the second preliminary structure 318. The sacrificial layer may be formed of, e.g., an oxide material or photoresist.

The sacrificial layer and the second preliminary structure 318 may be partially etched to expose a top surface of the first insulating pattern 308, so that the sacrificial pattern (not shown) and the second preliminary structure 318 in the shape of a “U” may be formed.

Referring to FIG. 19, the sacrificial pattern may be removed from the substrate 300. The sacrificial pattern may be removed using, e.g., an ashing process and a strip process. When the sacrificial pattern is removed, a first opening defined by the second preliminary structure 318 in the shape of a “U” may be formed.

A third preliminary structure 320 including a metal nitride material containing the element X may be formed on the second preliminary structure 318 in the shape of a “U”. For example, the third preliminary structure 320 may be titanium nitride material. The element X may include at least one selected from the group of Si, B, Al, O, and C.

The third preliminary structure 320 may be serially formed along a surface profile of the second preliminary structure 318 in the shape of a “U”. The third preliminary structure 320 may be formed conformally without filling the first opening defined by the second preliminary structure 318 in the shape of a “U”.

According to example embodiments, the process of forming the third preliminary structure 320 will be now described in further detail. A thermal or plasma thermal treatment using a first precursor including nitrogen and a second precursor including the element X may be performed on the substrate 300 on which the second preliminary structure 318 in the shape of a “U” is formed. The first precursor may include, e.g., NH₃ or N₂, and the element X of the second precursor may include at least one selected from the group of Si, B, Al, O, and C.

When the element X is silicon, the second precursor may include, e.g., at least one selected from the group of SiH₄, Si₂H₆, Si₃H₈, SiCl₂H₂, and BTBAS.

When the element X is boron, the second precursor may include, e.g., at least one selected from the group of B₂H₆ and TEB.

When the element X is aluminum, the second precursor may include, e.g., at least one selected from the group of AlCl₃, TEMAH, DMAH, and DMEAA.

When the element X is oxygen, the second precursor may include, e.g., at least one selected from the group of O₂ gas and O₃ gas.

When the element X is carbon, the second precursor may include, e.g., C₂H₄.

While the thermal or plasma thermal treatment using the first and second precursors is performed, an upper part of the second preliminary structure 318 in the shape of a “U” may be converted into titanium nitride material including the element X, so that the third preliminary structure 320 may be formed on the second preliminary structure 318 in the shape of a “U”.

According to example embodiments, while the thermal or plasma thermal treatment using the first and second precursors is performed, a third precursor including Ti may be further injected. In such a case, the generated results may be the third preliminary structure 320 including titanium nitride materials containing the element X on the second preliminary structure 318. A content of Ti of the third preliminary structure 320 may be higher.

According to another example embodiment, a fourth preliminary structure (not shown) including titanium nitride material containing an element Y may be further formed on the third preliminary structure 320. The fourth preliminary structure may be serially formed along a surface profile of the third preliminary structure 320. The fourth preliminary structure may be conformably formed without filling the first opening. The element Y may include at least one selected from the group of Si, B, Al, O, and C. The fourth preliminary structure may be formed using substantially the same process as that of forming the third preliminary structure 320. Further, the fourth preliminary structure may be formed in substantially the same in-situ chamber as the chamber in which the third structure 326 is formed.

According to still another example embodiment, before forming the third preliminary structure 320, a fourth preliminary structure (not shown) including TiO₂ may be further formed on the second preliminary structure 318. The fourth preliminary structure may be formed in substantially the same in-situ chamber as the chamber in which the third structure 326 is formed.

A second insulating layer (not shown) may be formed on the third preliminary structure 320. The second insulating layer may be formed to fully fill the first opening.

The second insulating layer may be partially etched to expose a top surface of the third preliminary structure 320, so that a second insulating pattern 322 may be formed. The second insulating pattern 322 may be formed to fully fill an opening defined by the third preliminary structure 320.

A top surface of the second insulating pattern 322 may be positioned on substantially the same level as that of the third preliminary structure.

Referring back to FIG. 20, a mask (not shown) may be formed on the first insulating pattern 308, the second insulating pattern 322, and the third preliminary structure 320. The mask may be formed to partially cover the third preliminary structure 320. The third preliminary structure 320, the second preliminary structure 318 in the shape of a “U”, the first insulating pattern 308, and the second insulating pattern 322 may be partially etched using the fourth mask as an etch mask, so that a third structure 326 and a second structure 324 may be formed. The second structure 324 and the third structure 326 may be in the shape of an “L” or a “J” depending on an etch depth and a location.

According to an example embodiment, the second structure 324 may be in the shape of an “L”. In this case, the second structure 324 may include a lower part of a first width and an upper part of a second width. The first width may be substantially greater than the second width. The second structure 324 may include a first vertical surface V1 in contact with the first insulating pattern 308, a first horizontal surface H1 horizontally extending from a lower part of the first vertical surface V1, a second horizontal surface H2 horizontally extending from an upper part of the first vertical surface V1, a third horizontal surface H3 parallel to the second horizontal surface H2 and spaced apart a predetermined space therefrom, a second vertical surface V2 connecting the second horizontal surface H2 to the third horizontal surface H3, and a third vertical surface V3 connecting the first horizontal surface H1 to the third horizontal surface H3. The third structure 326 may be formed on the second horizontal surface H2, the second vertical surface V2, and the third vertical surface V3 of the second structure 324.

While the etching process is performed using the mask, a second opening (not shown) may be formed by the first insulating pattern 308, the second insulating pattern 322, the second structure 324, and the third structure 326. A third insulating layer (not shown) may be formed on the first insulating pattern 308, the second insulating pattern 322, the second structure 324, and the third structure 326. The third insulating layer may be formed of an oxide material, a nitride material, or an oxynitride material, which may be silicon oxide material, silicon nitride material, and silicon oxynitride material, respectively.

An upper part of the third insulating layer may be removed to expose upper parts of the first insulating pattern 308, the second insulating pattern 322, the second structure 324, and the third structure 326. The removal process may be performed by a polishing process and an etch-back process. Upper parts of the first insulating pattern 308, the second insulating pattern 322, the third insulating pattern 328, and the third structure 326 may have substantially the same level.

A phase-change material layer (not shown) may be formed on the first insulating pattern 308, the second insulating pattern 322, the third insulating pattern 328, the second structure 324, and the third structure 326. The phase-change material layer may be formed to be electrically connected to the second structure 324 and the third structure 326.

A conductive layer (not shown) may be formed on the phase-change material layer. The conductive layer may be formed to be electrically connected to the phase-change material layer.

The conductive layer and the phase-change material layer may be partially etched to sequentially form a phase-change material pattern 330 and an upper electrode 332 on the first insulating pattern 308, the second insulating pattern 322, the third insulating pattern 328, and the third structure 326.

While it is not illustrated in detail, a bit line BL may be further formed on the upper electrode 332.

The following Experiment is provided in order to set forth particular details of one or more example embodiments. However, it will be understood that example embodiments are not limited to the particular details described in the Experiment, nor are comparative examples to be construed as either limiting the scope of the invention or as necessarily being outside the scope of the invention in every respect.

### EXPERIMENTAL EXAMPLE

FIG. 21 illustrates transition characteristics of a conventional phase-change memory device, and FIG. 22 illustrates transition characteristics of a phase-change memory according to a first example embodiment. A current applied to the phase-change memory device is plotted on the horizontal axes of FIGS. 21 and 22 in units of μA. A resistance measured in the phase-change memory device is plotted on the vertical axes of FIGS. 21 and 22, in units of Ω.

Referring to FIG. 21, a lower electrode in which a first structure including titanium silicide having a thickness of about 15 Å and a second structure including titanium nitride material having a thickness of about 80 Å are stacked may be formed. Transition characteristics of the phase-change memory device including the lower electrode were tested. As illustrated in FIG. 21, the phase-change memory device exhibited a reset current of about 280 Å.

Referring to FIG. 22, a lower electrode in which a first structure including titanium silicide having a thickness of about 20 Å and a second structure including titanium nitride material containing silicon having a thickness of about 80 Å are stacked is formed. Transition characteristics of the phase-change memory device including the lower electrode were tested. As illustrated in FIG. 19, the phase-change memory device exhibited a reset current of about 230 μA.

Referring to FIGS. 21 and 22, it is observed that a reset current of the phase-change memory device according to the first example embodiment was about 230 μA, and it was reduced by as much as 50 μA compared with the conventional phase-change memory device.

FIG. 23 illustrates endurance characteristics of a phase-change memory device according to a first example embodiment.

Referring to FIG. 23, a lower electrode including a first structure in which titanium silicide having a thickness of about 20 Å, a second structure including titanium nitride material having a thickness of about 80 Å, and a third structure including titanium nitride material containing silicon having a thickness of about 15 , A are stacked is formed. Transition characteristics of the phase-change memory device including the lower electrode were tested. The endurance test was carried out at a temperature of about 140 ° C. for about 12 hours.

The number of operation tests performed on the phase-change memory device is plotted on the horizontal axis of FIG. 23 in units of cycles. A resistance measured in the phase-change memory device is plotted on the vertical axis of FIG. 23 in units of Ω. As illustrated in FIG. 23, the phase-change memory device went through the endurance test of a cycle of about 10⁷. That is, the phase-change memory device according to example embodiments has excellent endurance.

In general, various materials of a lower electrode are required. In particular, development of a lower electrode in which a lower part has a low resistance, and thus is fowled of a material favorable to current supply, and an upper part is formed of a material capable of increasing resistivity and improving heat generation efficiency by a Joule heater to reduce a reset current, is needed.

According to example embodiments, a first structure including titanium silicide and a second structure including titanium nitride material form a lower part of a lower electrode of a low resistance, so that supply of current applied to a phase-change memory device can be facilitated. Also, a third structure including titanium nitride material including an element X forms an upper part of the lower electrode exhibiting high resistivity, so that operating current can be reduced.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A phase-change memory device, comprising:
a lower electrode;
a phase-change material pattern electrically connected to the lower electrode; and
an upper electrode electrically connected to the phase-change material pattern,
wherein the lower electrode includes:
a first structure including a metal semiconductor compound,
a second structure on the first structure, the second structure including a metal nitride material, and including a lower part having a greater width than an upper part, and
a third structure including a metal nitride material containing an element X, the third structure being on the second structure, the element X including at least one selected from the group of silicon, boron, aluminum, oxygen, and carbon.

2. The device as claimed in claim 1, wherein:
the second structure includes a lower part having a first width and an upper part having a second width smaller than the first width, and
the upper part of the second structure vertically extends from a top surface of the lower part.

3. The device as claimed in claim 2, wherein the second structure is in the shape of an “L” and the second structure includes a first vertical surface, a first horizontal surface horizontally extending from a lower part of the first vertical surface, a second horizontal surface horizontally extending from an upper part of the first vertical surface, a third horizontal surface parallel to the second horizontal surface and spaced apart a predetermined space therefrom, a second vertical surface connecting the second horizontal surface to the third horizontal surface, and a third vertical surface connecting the first horizontal surface to the third horizontal surface.

4. The device as claimed in claim 3, wherein the third structure is on the second horizontal surface.

5. The device as claimed in claim 3, further comprising an insulating pattern adjacent to the first vertical surface and the third vertical surface, wherein an upper part of the insulating pattern includes an oxide material containing the element X or a nitride material containing the element X.

6. The device as claimed in claim 5, wherein the upper part of the insulating pattern has a same thickness and level as the third structure.

7. The device as claimed in claim 3, wherein the third structure is on the second vertical surface and the third horizontal surface.

8. The device as claimed in claim 1, wherein the first structure includes titanium silicide, the second structure includes titanium nitride material, and the third structure includes titanium nitride material containing the element X.

9. The device as claimed in claim 1, further comprising a fourth structure including a metal oxide material between the second structure and the third structure.

10. The device as claimed in claim 9, wherein the fourth structure includes titanium oxide material.

11. The device as claimed in claim 1, further comprising a fourth structure including titanium nitride material containing an element Y on the third structure, wherein the element Y includes at least one selected from the group of silicon, boron, aluminum, oxygen, and carbon.

12. The device as claimed in claim 11, wherein the element Y is different from the element X.

13. The device as claimed in claim 1, further comprising a lower structure formed below the first structure and including silicon, wherein the first and second structures are formed by forming a metal layer on the lower structure and nitriding the result.

14. The device as claimed in claim 13, wherein the metal layer includes titanium.

15. The device as claimed in claim 13, wherein the third structure is formed by performing a thermal or plasma treatment using a first precursor containing nitrogen and a second precursor containing the element X on the second structure.

16. The device as claimed in claim 15, wherein the element X is Si, and the second precursor includes at least one selected from the group of SiR₄, Si₂H₆, Si₃H₈, SiCl₂H₂, and bis(tertiary-butylamino)silane.

17. The device as claimed in claim 15, wherein the element X is boron, and the second precursor includes at least one selected from the group of B₂H₆ and triethylborate.

18. The device as claimed in claim 15, wherein the element X is aluminum, and the second precursor includes at least one selected from the group of AlCl₃, tetra ethyl methyl amide hafnium, dimethyl aluminum hydride, and dimethylethylamine alane.

19. The device as claimed in claim 15, wherein the element X is oxygen, and the second precursor includes at least one selected from the group of oxygen gas and ozone gas.

20. The device as claimed in claim 15, wherein the element X is carbon, and the second precursor includes C₂H₄.
